(19) United States
(12) Patent Application Publication
(10) Pub. No.: US 2026/0150646 A1
(43) Pub. Date: May 28, 2026

(54) SEMICONDUCTOR DEVICES AND METHODS OF FORMING THE SAME

(71) Applicant: Taiwan Semiconductor Manufacturing Company, Ltd., Hsinchu (TW)

(72) Inventors: Ru-Shang Hsiao, Hsinchu City (TW); KeJing Yu, Hsinchu City (TW); Anhao Cheng, Hsinchu City (TW); Yen-Liang Lin, Hsinchu City (TW)

(73) Assignee: Taiwan Semiconductor Manufacturing Company, Ltd., Hsinchu (TW)

(21) Appl. No.: 18/960,632

(22) Filed: Nov. 26, 2024

(51) Int. Cl. H01L 23/528; H01L 23/522; H01L 27/06

(52) U.S. Cl. CPC H10W 20/427; H10D 88/00; H10W 20/496

(57) ABSTRACT

A semiconductor device includes a first substrate including first and second sides opposite to each other, a second substrate including first and second sides opposite to each other, epitaxial structures, a gate structure on the first side of the first substrate, a first metal layer and a second metal layer on the first side of the second substrate, a dielectric layer interposed between the first and second metal layers, and a bonding layer interposed between the second side of the first substrate and the second side of the second substrate. The first and second metal layers, and the dielectric layer operatively form a capacitor that is coupled to at least one epitaxial structure on the first side of the first substrate. Each of the first and second metal layers, and the dielectric layer includes a vertical portion extending toward or away from the first substrate.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of a semiconductor device, in accordance with some embodiments.

FIG. 2 illustrates a flowchart of an example method for fabricating a semiconductor device, in accordance with some embodiments.

FIG. 3A, FIG. 3B, FIG. 3C, and FIG. 3D illustrate a flow diagram of an example method for fabricating a semiconductor device, in accordance with some embodiments.

FIG. 4 illustrates a cross-sectional view of a semiconductor device, in accordance with some embodiments.

FIG. 5 illustrates a flowchart of an example method for fabricating a semiconductor device, in accordance with some embodiments.

FIG. 6A, FIG. 6B, FIG. 6C, and FIG. 6D illustrate a flow diagram of an example method for fabricating a semiconductor device, in accordance with some embodiments.

FIG. 7A, FIG. 7B, and FIG. 7C illustrate cross-sectional views of semiconductor devices, in accordance with some embodiments.

FIG. 8A and FIG. 8B illustrate cross-sectional views of semiconductor devices, in accordance with some embodiments.

FIG. 9 illustrates top views of semiconductor devices, in accordance with some embodiments.

FIG. 10 illustrates top views of semiconductor devices, in accordance with some embodiments.

FIG. 11 illustrates cross-sectional views of semiconductor devices, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Continued innovations in semiconductor process technologies are enabling higher integration densities and device scaling. As the semiconductor industry moves towards smaller technology nodes, planar and non-planar semiconductor field-effect-transistor (FET) device structures should be scaled to smaller dimensions to provide increased device width per footprint area. In this regard, nanostructure (e.g., nanosheet, nanowire, or otherwise gate-all-around (GAA)) FET devices are considered to be a viable option for continued complementary-metal-oxide-semiconductor (CMOS) scaling. In general, various structures can be incorporated into the semiconductor device. For example, a metal-insulator-metal (MIM) capacitor can be provided in a back-end-of-line (BEOL) side for high capacitance applications (e.g., global shutter, etc.).

The present disclosure provides a MIM capacitor embedded in a backside power rail of the semiconductor device, thereby enabling high capacitance. The techniques disclosed herein utilizes a three-dimensional (3D) MIM architecture that integrates a multi-layer film stack (e.g., metal/dielectric/metal, or metal/dielectric/metal/dielectric/metal) while offering enhanced capacitance and design flexibility. In some embodiments, a bowing profile can be utilized to enhance reliability and flexibility, for example by introducing a void. The techniques disclosed herein can be applied in different transistor types, including but not limited to, Metal-Oxide-Semiconductor devices, Fin Field-Effect-Transistor devices, Gate-All-Around devices, etc., regardless BEOL deep trench MIM structures.

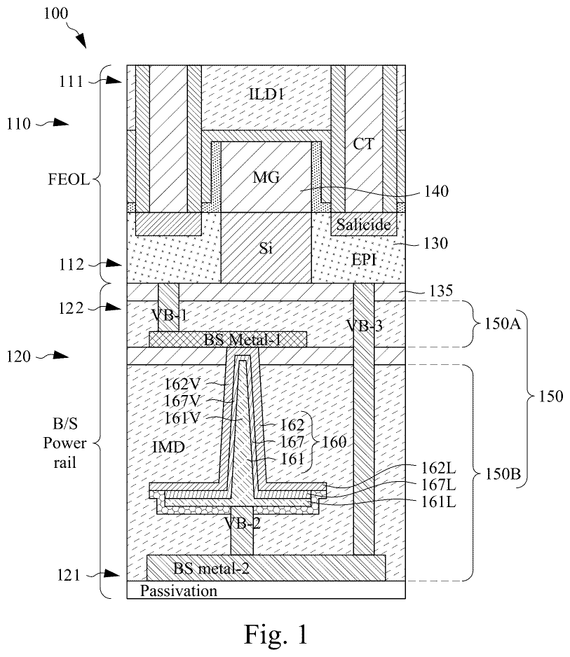

FIG. 1 illustrates a cross-sectional view of a semiconductor device 100, in accordance with some embodiments. The semiconductor device 100 includes a first substrate 110 including a first side 111 and a second side 112 opposite to each other, and a second substrate 120 including a first side 121 and a second side 122. In some embodiments, the first substrate 110 may be a front-end-of-line (FEOL) side. In some embodiments, the second substrate 120 may be a backside (B/S) power rail.

In some embodiments, the semiconductor device 100 includes a plurality of transistors formed on the first substrate 110. The semiconductor device 100 can include a plurality of epitaxial structures (EPI) 130 and a gate structure (MG) 140 formed on the first side 111 of the first substrate 110. The semiconductor device 100 can include source and drain (S/D) structures, contact structures (CT), etc., formed on the first substrate 110. The semiconductor device 100 can include one or more interlayer dielectric structures (e.g., ILD1).

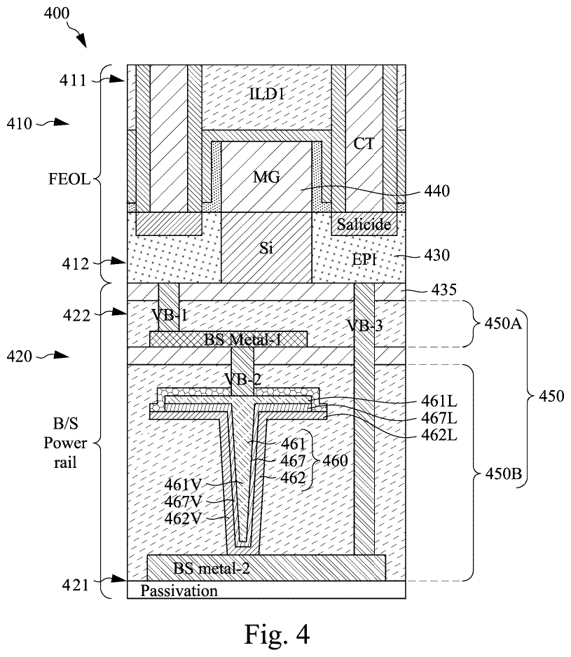

In some embodiments, the semiconductor device 100 includes a plurality of metallization layers 150 (e.g., metallization layers 150A, 150B, etc.) formed on the second substrate 120. In some embodiments, the semiconductor device 100 includes a first metal layer 161 formed on the second substrate 120, a second metal layer 162 formed on the second substrate 120, and a dielectric layer 167 interposed between the first metal layer 161 and the second metal layer 162. The first metal layer 161, the second metal layer 162, and the dielectric layer 167 can operatively form a capacitor on the first side 121 of the second substrate 120 that is coupled to at least one of the plurality of epitaxial structures 130 on the first side 111 of the first substrate 110. Each of the first metal layer 161, the dielectric layer 167, and the second metal layer 162 includes at least a vertical portion (e.g., vertical portions 161V, 167V, 162V, etc.) extending toward (as shown in FIG. 1) or away from (as shown in FIG. 4) the first substrate 110. In some embodiments, each of the first metal layer 161, the dielectric layer 167, and the second metal layer 162 can include at least a lateral portion (e.g., lateral portions 161L, 167L, 162L, etc.) connected to the corresponding vertical portion. In some embodiments, the semiconductor device 100 can include a bonding layer 135. The bonding layer 135 can be interposed between the second side 112 of the first substrate 110 and the second side 122 of the second substrate 120. In some embodiments, the bonding layer 135 can be formed on the second side 122 of the second substrate 120, as shown. In some embodiments, the bonding layer 135 can be formed on the second side 112 of the first substrate 110. The bonding layer 135 can be configured to bond the first substrate 110 with the second substrate 120. In some embodiments, the bonding layer 135 can be formed of a material including, but not limited to, dielectric (e.g., silicon dioxide, silicon nitride, silicon carbide), epitaxial film (e.g., silicon-germanium, silicon-phosphorus), metal oxide (e.g., aluminum oxide, zirconium oxide, hafnium oxide), etc.

In some embodiments, the first metal layer 161 is disposed in a first one (e.g., the metallization layer 150B formed on the second substrate 120) of the metallization layers 150, and the second metal layer 162 is disposed in a second one (e.g., the metallization layer 150A) of the metallization layers 150. For example, as shown, the first metal layer 161 can be electrically coupled to a metal structure (e.g., BS Metal-1) in the metallization layer 150A. The second metal layer 162 can be electrically coupled to a metal structure (e.g., BS Metal-2) in the metallization layer 150B, through a via structure (e.g., VB-2), a dielectric layer (e.g., the dielectric layer 167), a metal layer (e.g., the metal layer 161), etc. In some embodiments, the first metal layer 161 can be electrically coupled to a first one (e.g., a first S/D epitaxial structure) of the epitaxial structures 130, and the second metal layer 162 can be electrically coupled to a second one (e.g., a second S/D epitaxial structure) of the epitaxial structures 130. For example, as shown, the first metal layer 161 can be electrically coupled to the first one of the epitaxial structures 130 through the metal structure (e.g., BS Metal-1) and a via structure (e.g., VB-1), and the second metal layer 162 can be electrically coupled to the second one of the epitaxial structures 130 through the via structure (e.g., VB-2) and the metal structure (e.g., BS metal-2). In some embodiments, as shown, the plurality of epitaxial structures 130 can be laterally disposed on sides of the gate structure 140.

In some embodiments, the first metallization layer 150A and the second metallization layer 150B can be vertically disposed next to each other, with no other metallization layer interposed therebetween. In some embodiments, the first metallization layer 150A and the second metallization layer 150B can be vertically disposed next to each other, with at least another of the metallization layers 150 interposed therebetween.

In some embodiments, the first metal layer 161, the dielectric layer 167, and the second metal layer 162 can operatively form a capacitor 160. In some embodiments, the dielectric layer 167 includes a high-k dielectric material (e.g., Zirconium Oxide, Aluminum Oxide, Hafnium Oxide, etc.). In some embodiments, the dielectric layer 167 can include and/or be formed of any material with a dielectric constant larger than 10. In some embodiments, the dielectric layer 167 includes a ferroelectric material. In some embodiments, the first metal layer 161 and the second metal layer 162 each include copper. In some embodiments, the first metal layer 161 and the second metal layer 162 each include aluminum. In some embodiments, the first metal layer 161 and the second metal layer 162 can include Titanium nitride (TiN), titanium, tantalum nitride (TaN), tantalum, copper (Cu), cobalt (Co), aluminum (Al), etc. In some embodiments, each of the first metal layer 161 and the second metal layer 162 can be or include a different material.

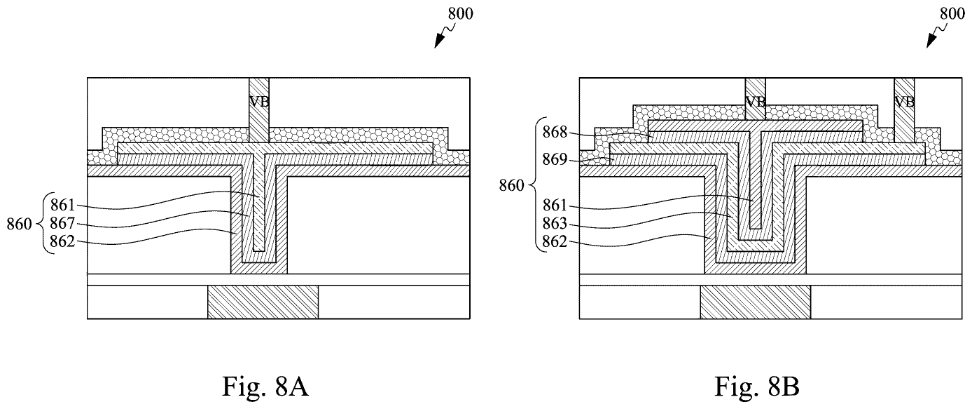

In some embodiments, the capacitor 160 can include a third metal layer formed between the first metal layer 161 and the second metal layer 162, within the dielectric layer 167 (e.g., as shown in FIG. 8). In some embodiments, the first metal layer 161, the second metal layer 162, the third metal layer within the dielectric layer 167, and the dielectric layer 167 can form capacitors that are connected in parallel to each other.

It should be understood that the semiconductor device 100 of FIG. 1 is a non-limiting example and simplified for illustrative purposes, and thus, the semiconductor device 100 can include any of various other components or structures, while remaining within the scope of the present disclosure. In some embodiments, the semiconductor device 100 can include more, fewer, or different components than shown in or described with respect to FIG. 1. Subsequent figures refer to these reference cross-sections for clarity.

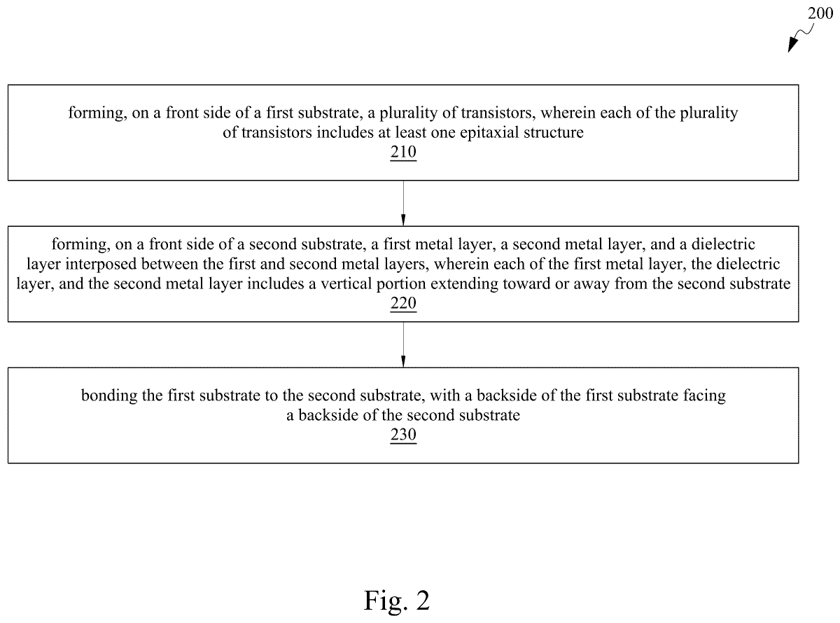

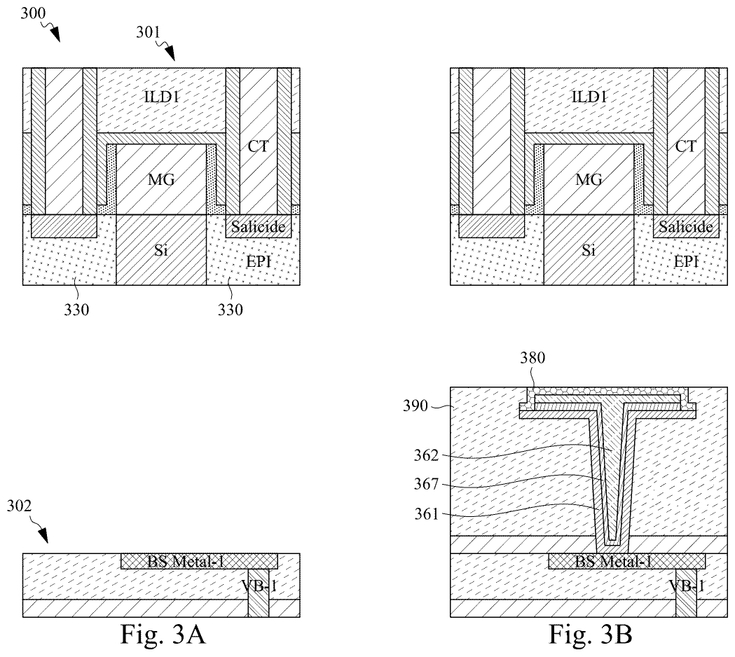

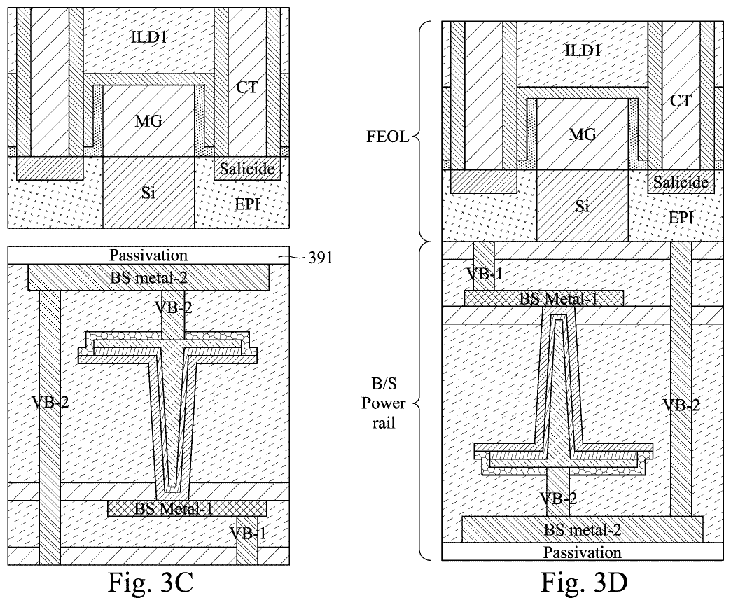

FIG. 2 illustrates a flowchart of an example method 200 for fabricating a semiconductor device, in accordance with some embodiments. For example, at least some of the operations (or steps) in the method 200 can be used to form the semiconductor device 100 shown in FIG. 1 or the like. It is noted that the method 200 is a non-limiting example. Accordingly, additional operations may be provided before, during, and after the method 200 of FIG. 2, and that some other operations may only be briefly described herein. In some embodiments, operations of the method 200 may be associated with an example semiconductor device at various fabrication stages shown in FIG. 3A, FIG. 3B, FIG. 3C, and FIG. 3D, which will be discussed in further detail below. In some embodiments, the flow diagram shown in FIG. 3A, FIG. 3B, FIG. 3C, and FIG. 3D may be associated with operations of the method 200.

In brief overview, the method 200 starts with operation 210 of forming, on a front side of a first substrate, a plurality of transistors, wherein each of the plurality of transistors includes at least one epitaxial structure. The method 200 continues to operation 220 of forming, on a front side of a second substrate, a first metal layer, a second metal layer, and a dielectric layer interposed between the first and second metal layers, wherein each of the first metal layer, the dielectric layer, and the second metal layer includes a vertical portion extending toward or away from the second substrate. The method 200 continues to operation 230 of bonding the first substrate to the second substrate, with a backside of the first substrate facing a backside of the second substrate. FIG. 3A, FIG. 3B, FIG. 3C, and FIG. 3D each can illustrate a portion of the semiconductor device 100 at various fabrication stages of the method 200 in FIG. 2.

Corresponding to operation 210 of FIG. 2, FIG. 3A is a cross-sectional view of a semiconductor device 300 including a first substrate 301 and a second substrate 302. In some embodiments, each of the first substrate 301 and the second substrate 302 may be a semiconductor substrate, such as a bulk semiconductor, a semiconductor-on-insulator (SOI) substrate, or the like, which may be doped (e.g., with a p-type or an n-type dopant) or undoped. In some embodiments, each of the first substrate 301 and the second substrate 302 may be a wafer, such as a silicon wafer. Generally, an SOI substrate includes a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of each of the first substrate 301 and the second substrate 302 may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

At operation 210, on a front side of the first substrate 301, a plurality of transistors can be formed. In some embodiments, each of the plurality of transistors can include at least one epitaxial structure (e.g., EPI; S/D structures) 330. In some embodiments, the epitaxial structure 330 can be doped. For example, when the semiconductor device 300 is configured in n-type (and operates in an enhancement mode), each of the epitaxial structures 330 may be silicon that is doped with a p-type dopant such as boron (B), aluminum (Al), indium (In), and gallium (Ga); and when the semiconductor device 300 is configured in p-type (and operates in an enhancement mode), each of the epitaxial structures 330 may be silicon that is doped with an n-type dopant such as phosphorus (P), arsenic (As), antimony (Sb). The epitaxial structure 330 may include materials, for example, a compound semiconductor such as silicon carbide, gallium arsenide, gallium phosphide, indium phosphide, indium arsenide, and/or indium antimonide, an alloy semiconductor such as GaAsP, AlInAs, AlGaAs, InGaAs, GaInP, and/or GaInAsP, or combinations thereof. The epitaxial structure 330 may be epitaxially grown on the front side of the first substrate 301, using for example, a molecular beam epitaxy (MBE) process, a chemical vapor deposition (CVD) process such as a metal organic CVD (MOCVD) process, and/or other suitable epitaxial growth processes. At operation 210, on the second substrate 302, a via structure (e.g., VB1) and a metal structure (e.g., BS Metal-1) can be formed using, for example, photolithography and etching techniques. In some embodiments, a planarization process, such as a chemical mechanical polish (CMP) process, may be used to form a top surface of the second substrate 302.

Corresponding to operation 220 of FIG. 2, FIG. 3B is a cross-sectional view of the semiconductor device 300, in which, on a front side of the second substrate 302, a first metal layer 361, a second metal layer 362, and a dielectric layer 367 interposed between the first metal layer 361 and second metal layer 362 are formed. Each of the first metal layer 361, the dielectric layer 367, and the second metal layer 362 includes a vertical portion extending toward or away from the second substrate 302.

At operation 220, an interlayer dielectric 390 can be formed over the frontside of the second substrate 302. In some embodiments, the interlayer dielectric 390 may be deposited using low-pressure chemical vapor deposition (LPCVD) or plasma enhanced chemical vapor deposition (PECVD). Then, the interlayer dielectric 390 can be etched to form a trench (or an opening). For example, photoresist material is used to pattern the interlayer dielectric 390 to form a patterned mask. The patterned mask may be subsequently used to pattern exposed portions of the interlayer dielectric 390 to form the trench where the first metal layer 361, the second metal layer 362, and the dielectric layer 367 can be formed. In some embodiments, the trench can be formed using, for example, reactive ion etch (RIE), neutral beam etch (NBE), the like, or combinations thereof. The etching process may be anisotropic.

Then, each of the first metal layer 361, the second metal layer 362, and the dielectric layer 367 can be formed. In some embodiments, each of the first metal layer 361, the second metal layer 362, and the dielectric layer 367 may be deposited onto the deep trench area using low-pressure chemical vapor deposition (LPCVD) or plasma enhanced chemical vapor deposition (PECVD), for example. In some embodiments, a metal material can be deposited to at least line the trench thereby forming the first metal layer 361. And then a dielectric material can be deposited to at least line the trench (e.g., lined with the first metal layer 361) thereby forming the dielectric layer 367. The metal material can be deposited to fill the trench thereby forming the second metal layer 362. In some embodiments, a cap layer (e.g., Silicon Nitride) 380 may be deposited on a portion of the first metal layer 361, the second metal layer 362, and the dielectric layer 367. In some embodiments, at operation 220, various other structures including via structures (e.g., VB-2), metal structures (e.g., BS metal-2), passivation structures (e.g., a passivation structure 391), etc. can be formed, for example as shown in FIG. 3C. In some embodiments, the passivation structure 391 can include a dielectric material (e.g., silicon dioxide, silicon nitride, silicon carbide), etc.

Corresponding to operation 230 of FIG. 2, FIG. 3D is a cross-sectional view of the semiconductor device 300, in which, the first substrate 301 is bonded to the second substrate 302, with a backside of the first substrate 301 facing a backside of the second substrate 302. The first substrate 301 and the second substrate 302 can be coupled or bonded to each other by any suitable wafer bonding process (e.g., based on the bonding layer 135 of FIG. 1).

FIG. 4 illustrates a cross-sectional view of a semiconductor device 400, in accordance with some embodiments. The semiconductor device 400 includes a first substrate 410 including a first side 411 and a second side 412 opposite to each other, and a second substrate 420 including a first side 421 and a second side 422. In some embodiments, the first substrate 410 may be a front-end-of-line (FEOL) side. In some embodiments, the second substrate 420 may be a backside (B/S) power rail. As shown, the semiconductor device 400 may be substantially similar to and/or incorporate features of the semiconductor device 100. For example, the semiconductor device 400 may include a capacitor whose orientation (e.g., of a vertical portion extending toward or away from the substrate) is opposite to the capacitor 160 of the semiconductor device 100.

In some embodiments, the semiconductor device 400 includes a plurality of transistors formed on the first substrate 410. The semiconductor device 400 can include a plurality of epitaxial structures (EPI) 430 and a gate structure (MG) 440 formed on the first side 411 of the first substrate 410. The semiconductor device 400 can include source and drain (S/D) structures, contact structures (CT), etc., formed on the first substrate 410. The semiconductor device 400 can include one or more interlayer dielectric structures (e.g., ILD1).

The semiconductor device 400 includes a plurality of metallization layers 450 (e.g., metallization layers 450A, 450B, etc.) formed on the second substrate 420. The semiconductor device 400 includes a first metal layer 461 formed on the second substrate 420, a second metal layer 462 formed on the second substrate 420, and a dielectric layer 467 interposed between the first metal layer 461 and the second metal layer 462. The first metal layer 461, the second metal layer 462, and the dielectric layer 467 can operatively form a capacitor on the second substrate 420 that is coupled to at least one of the plurality of epitaxial structures 430 on the first side 411 of the first substrate 410. Each of the first metal layer 461, the dielectric layer 467, and the second metal layer 462 includes at least a vertical portion (e.g., vertical portions 461V, 467V, 462V, etc.) extending toward (as shown in FIG. 1) or away from (as shown in FIG. 4) the first substrate 410. In some embodiments, each of the first metal layer 461, the dielectric layer 467, and the second metal layer 462 can include at least a lateral portion (e.g., lateral portions 461L, 467L, 462L, etc.) connected to the corresponding vertical portion. In some embodiments, the semiconductor device 400 can include a bonding layer 435. The bonding layer 435 can be interposed between the second side 412 of the first substrate 410 and the second side 422 of the second substrate 420. In some embodiments, the bonding layer 435 can be formed on the second side 422 of the second substrate 420. In some embodiments, the bonding layer 435 can be formed on the second side 412 of the first substrate 410. The bonding layer 435 can be configured to bond the first substrate 410 with the second substrate 420.

In some embodiments, the first metal layer 461 is electrically coupled to and/or disposed in a first one (e.g., the metallization layer 450A formed on the second substrate 420) of the metallization layers 450, and the second metal layer 462 is electrically coupled to and/or disposed in a second one (e.g., the metallization layer 450B) of the metallization layers 450. For example, as shown, the first metal layer 461 can be electrically coupled to a metal structure (e.g., BS Metal-1) in the metallization layer 450A through a metal structure (e.g., BS Metal-1). The second metal layer 462 can be electrically coupled to a metal structure (e.g., BS Metal-2) in the metallization layer 450B. In some embodiments, the first metal layer 461 can be electrically coupled to a first one (e.g., a first S/D epitaxial structure) of the epitaxial structures 430, and the second metal layer 462 can be electrically coupled to a second one (e.g., a second S/D epitaxial structure) of the epitaxial structures 430. For example, as shown, the first metal layer 461 can be electrically coupled to the first one of the epitaxial structures 430 through the metal structure (e.g., BS Metal-1) and the via structures (e.g., VB-1, VB-2), and the second metal layer 462 can be electrically coupled to the second one of the epitaxial structures 430 through the via structure (e.g., VB-3) and the metal structure (e.g., BS metal-2). In some embodiments, as shown, the plurality of epitaxial structures 430 can be laterally disposed on sides of the gate structure 440.

In some embodiments, the first metallization layer 450A and the second metallization layer 450B can be vertically disposed next to each other, with no other metallization layer interposed therebetween. In some embodiments, the first metallization layer 450A and the second metallization layer 450B can be vertically disposed next to each other, with at least another of the metallization layers 450 interposed therebetween.

In some embodiments, the first metal layer 461, the dielectric layer 467, and the second metal layer 462 can operatively form a capacitor 460. In some embodiments, the dielectric layer 467 includes a high-k dielectric material (e.g., Zirconium Oxide, Aluminum Oxide, Hafnium Oxide, etc.). In some embodiments, the dielectric layer 467 includes a ferroelectric material. In some embodiments, the first metal layer 461 and the second metal layer 462 each include copper. In some embodiments, the first metal layer 461 and the second metal layer 462 each include aluminum. In some embodiments, the first metal layer 461 and the second metal layer 462 can include Titanium Nitride, Titanium, Tantalum Nitride, Tantalum, etc.

In some embodiments, the capacitor 460 can include a third metal layer formed between the first metal layer 461 and the second metal layer 162, within the dielectric layer 467 (e.g., as shown in FIG. 8). In some embodiments, the first metal layer 461, the second metal layer 462, the third metal layer within the dielectric layer 467, and the dielectric layer 467 can form capacitors that are connected in parallel to each other.

It should be understood that the semiconductor device 400 of FIG. 4 is a non-limiting example and simplified for illustrative purposes, and thus, the semiconductor device 400 can include any of various other components or structures, while remaining within the scope of the present disclosure. In some embodiments, the semiconductor device 400 can include more, fewer, or different components than shown in or described with respect to FIG. 4. Subsequent figures refer to these reference cross-sections for clarity.

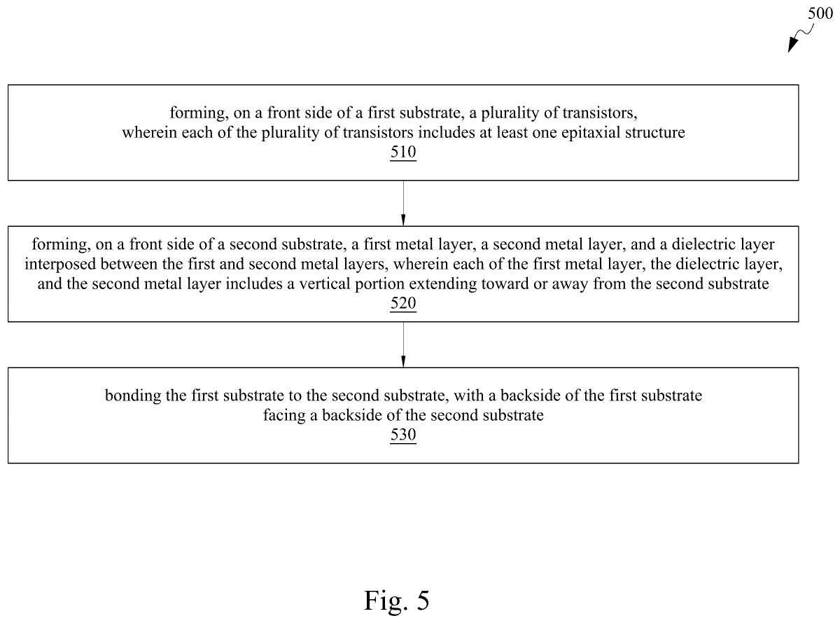

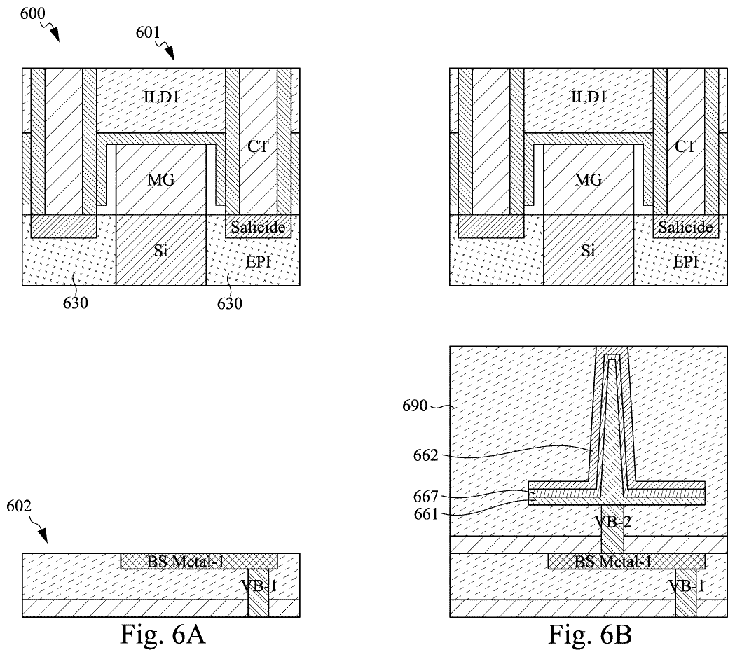

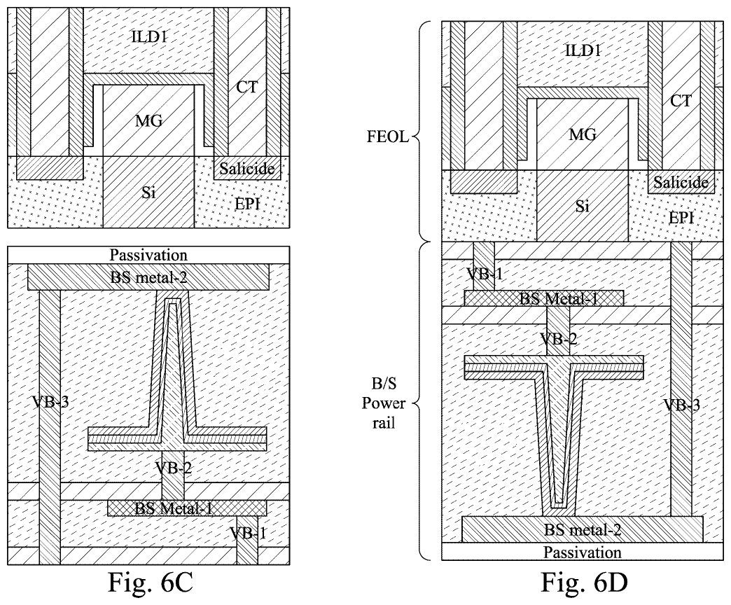

FIG. 5 illustrates a flowchart of an example method 500 for fabricating a semiconductor device, in accordance with some embodiments. For example, at least some of the operations (or steps) in the method 500 can be used to form the semiconductor device 400 shown in FIG. 4 or the like. It is noted that the method 500 is a non-limiting example. Accordingly, additional operations may be provided before, during, and after the method 500 of FIG. 5, and that some other operations may only be briefly described herein. In some embodiments, operations of the method 500 may be associated with an example semiconductor device at various fabrication stages shown in FIG. 6A, FIG. 6B, FIG. 6C, and FIG. 6D, which will be discussed in further detail below. In some embodiments, the flow diagram shown in FIG. 6A, FIG. 6B, FIG. 6C, and FIG. 6D may be associated with operations of the method 500.

In brief overview, the method 500 starts with operation 510 of forming, on a front side of a first substrate, a plurality of transistors, wherein each of the plurality of transistors includes at least one epitaxial structure. The method 500 continues to operation 520 of forming, on a front side of a second substrate, a first metal layer, a second metal layer, and a dielectric layer interposed between the first and second metal layers, wherein each of the first metal layer, the dielectric layer, and the second metal layer includes a vertical portion extending toward or away from the second substrate. The method 500 continues to operation 530 of bonding the first substrate to the second substrate, with a backside of the first substrate facing a backside of the second substrate. FIG. 6A, FIG. 6B, FIG. 6C, and FIG. 6D each can illustrate a portion of the semiconductor device 400 at various fabrication stages of the method 500 in FIG. 5.

Corresponding to operation 510 of FIG. 5, FIG. 6A is a cross-sectional view of a semiconductor device 600 including a first substrate 601 and a second substrate 602. In some embodiments, each of the first substrate 601 and the second substrate 602 may be a semiconductor substrate, such as a bulk semiconductor, a semiconductor-on-insulator (SOI) substrate, or the like, which may be doped (e.g., with a p-type or an n-type dopant) or undoped. In some embodiments, each of the first substrate 601 and the second substrate 602 may be a wafer, such as a silicon wafer. Generally, an SOI substrate includes a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of each of the first substrate 601 and the second substrate 602 may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

At operation 510, on a front side of the first substrate 601, a plurality of transistors can be formed. In some embodiments, each of the plurality of transistors can include at least one epitaxial structure (e.g., EPI; S/D structures) 630. In some embodiments, the epitaxial structure 630 can be doped. For example, when the semiconductor device 600 is configured in n-type (and operates in an enhancement mode), each of the epitaxial structures 630 may be silicon that is doped with a p-type dopant such as boron (B), aluminum (Al), indium (In), and gallium (Ga); and when the semiconductor device 600 is configured in p-type (and operates in an enhancement mode), each of the epitaxial structures 630 may be silicon that is doped with an n-type dopant such as phosphorus (P), arsenic (As), antimony (Sb). The epitaxial structure 630 may include materials, for example, a compound semiconductor such as silicon carbide, gallium arsenide, gallium phosphide, indium phosphide, indium arsenide, and/or indium antimonide, an alloy semiconductor such as GaAsP, AlInAs, AlGaAs, InGaAs, GaInP, and/or GaInAsP, or combinations thereof. The epitaxial structure 630 may be epitaxially grown on the front side of the first substrate 601, using for example, a molecular beam epitaxy (MBE) process, a chemical vapor deposition (CVD) process such as a metal organic CVD (MOCVD) process, and/or other suitable epitaxial growth processes. At operation 510, on the second substrate 602, a via structure (e.g., VB1) and a metal structure (e.g., BS Metal-1) can be formed using, for example, photolithography and etching techniques. In some embodiments, a planarization process, such as a chemical mechanical polish (CMP) process, may be used to form a top surface of the second substrate 602.

Corresponding to operation 520 of FIG. 5, FIG. 6B is a cross-sectional view of the semiconductor device 600, in which, on a front side of the second substrate 602, a first metal layer 661, a second metal layer 662, and a dielectric layer 667 interposed between the first metal layer 661 and second metal layer 662 are formed. Each of the first metal layer 661, the dielectric layer 667, and the second metal layer 662 includes a vertical portion extending toward or away from the second substrate 602.

At operation 520, each of a first metal layer 661, a second metal layer 662, and a dielectric layer 667 can be formed. In some embodiments, each of the first metal layer 661, the second metal layer 662, and the dielectric layer 667 may be deposited over the second substrate 602 using low-pressure chemical vapor deposition (LPCVD) or plasma enhanced chemical vapor deposition (PECVD), for example. In some embodiments, a metal material can be deposited over the frontside of the second substrate 602 and then etched thereby forming the first metal layer 661. And then a dielectric material can be deposited to line the first metal layer 661 thereby forming the dielectric layer 667. The metal material can be deposited to line the dielectric layer 667 thereby forming the second metal layer 662. In some embodiments, although not shown, a cap layer (e.g., Silicon Nitride) may be deposited on a portion of the first metal layer 661, the second metal layer 662, and the dielectric layer 667. And then, an interlayer dielectric 690 can be formed over the first metal layer 661, the second metal layer 662, and the dielectric layer 667. In some embodiments, the interlayer dielectric 690 may be deposited using low-pressure chemical vapor deposition (LPCVD) or plasma enhanced chemical vapor deposition (PECVD). In some embodiments, at operation 520, various other structures including via structures (e.g., VB-3), metal structures (e.g., BS metal-2), passivation structures, etc. can be formed, for example as shown in FIG. 6C.

Corresponding to operation 530 of FIG. 5, FIG. 6D is a cross-sectional view of the semiconductor device 600, in which, the first substrate 601 is bonded to the second substrate 602, with a backside of the first substrate 601 facing a backside of the second substrate 602. The first substrate 601 and the second substrate 602 can be coupled or bonded to each other by any suitable wafer bonding process.

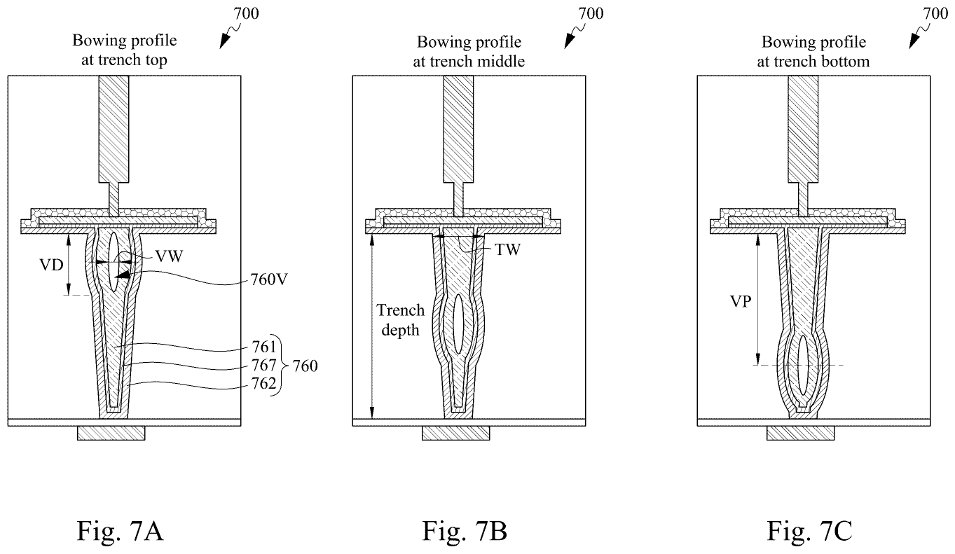

FIG. 7A, FIG. 7B, and FIG. 7C illustrate cross-sectional views of a semiconductor device 700, in accordance with some embodiments. Shown in the figures are non-limiting examples. In some embodiments, the semiconductor device 700 can include more, fewer, or different components than shown in or described with respect to the figures. In some embodiments, the semiconductor device 700 may be substantially similar to or incorporate features of the semiconductor devices 100, 400, etc. For example, as shown in the figures, the semiconductor device 700 includes a capacitor 760, including a first metal layer 761, a second metal layer 762, and a dielectric layer 767. As shown in the figures, the capacitor 760 includes a vertical portion extending toward a bottom side of the substrate. Although not shown, in some embodiments, the capacitor 760 can include a vertical portion extending away from the bottom side of the substrate.

As opposed to the semiconductor devices 100, 400, the semiconductor device 700 can include a void 760V. As shown in FIG. 7A, FIG. 7B, and FIG. 7C, the capacitor 760 can include the void 760V inside the first metal layer 761. In FIG. 7A, the semiconductor device 700 includes the void 760V at a top portion of the trench; in FIG. 7B, the semiconductor device 700 includes the void 760V at a middle portion of the trench; and in FIG. 7C, the semiconductor device 700 includes the void 760V at a bottom portion of the trench. The depth of the void 760V can be defined as VD; the width of the void 760V can be defined as VW; the width of the trench can be defined as TW; and the position of the void 760V can be defined as VP. In some embodiments, the width VW of the void 760V can be 1 to 20% of the trench width TW, the depth VD of the void 760V can be 10 to 50% of the trench depth TD. In some embodiments, the position VP of the void 760V (e.g., from the trench top to the void center) can be located at 2 to 50% of the trench depth TD, at the middle point, or at the bottom (e.g., 50 to 98% of the trench depth TD). The void 760V allows for bowing profile as shown in the figures, which releases stress, especially when the semiconductor device is utilized as an array (e.g., three-dimensional MIM capacitor array for image sensor applications).

It should be understood that the semiconductor device 700 of FIG. 7A, FIG. 7B, and FIG. 7C is a non-limiting example and simplified for illustrative purposes, and thus, the semiconductor device 700 can include any of various other components or structures, while remaining within the scope of the present disclosure. In some embodiments, the semiconductor device 700 can include more, fewer, or different components than shown in or described with respect to FIG. 7A, FIG. 7B, and FIG. 7C.

FIG. 8A and FIG. 8B illustrate cross-sectional views of a semiconductor device 800, in accordance with some embodiments. Shown in the figures are non-limiting examples. In some embodiments, the semiconductor device 800 can include more, fewer, or different components than shown in or described with respect to the figures. In some embodiments, the semiconductor device 800 may be substantially similar to or incorporate features of the semiconductor devices 100, 400, etc. For example, as shown in FIG. 8A, the semiconductor device 800 includes a capacitor 860, including a first metal layer 861, a second metal layer 862, and a dielectric layer 867. The capacitor 860 can include a vertical portion extending toward a bottom side of the substrate. Although not shown, in some embodiments, the capacitor 860 can include a vertical portion extending away from the bottom side of the substrate.

As opposed to the semiconductor devices 100, 400, or the semiconductor device 800 shown in FIG. 8A, the semiconductor device 800 shown in FIG. 8B can include a third metal layer 863 formed between the first metal layer 861 and the second metal layer 862, within the dielectric layer 867 of FIG. 8A (or between a first dielectric layer 868 and a second dielectric layer 869, as shown in FIG. 8B). In some embodiments, the first metal layer 861, the second metal layer 862, the third metal layer 863, and the dielectric layers 868, 869 form capacitors that are connected in parallel to each other. In some embodiments, as shown, the third metal layer 863 can be connected (e.g., to an epitaxial structure) through a via structure.

In some embodiments, the first metal layer 861, the second metal layer 862, and the third metal layer 863 can be different. For example, one of the first metal layer 861, the second metal layer 862, and the third metal layer 863 may include a different material. Each of the first metal layer 861, the second metal layer 862, and the third metal layer 863 may be or include a different metal. In some embodiments, the dielectric layer 868 and the dielectric layer 869 can be different. For example, each of the dielectric layer 868 and the dielectric layer 869 may be or include a different dielectric material.

It should be understood that the semiconductor device 800 of FIG. 8A and FIG. 8B is a non-limiting example and simplified for illustrative purposes, and thus, the semiconductor device 800 can include any of various other components or structures, while remaining within the scope of the present disclosure. In some embodiments, the semiconductor device 800 can include more, fewer, or different components than shown in or described with respect to FIG. 8A and FIG. 8B.

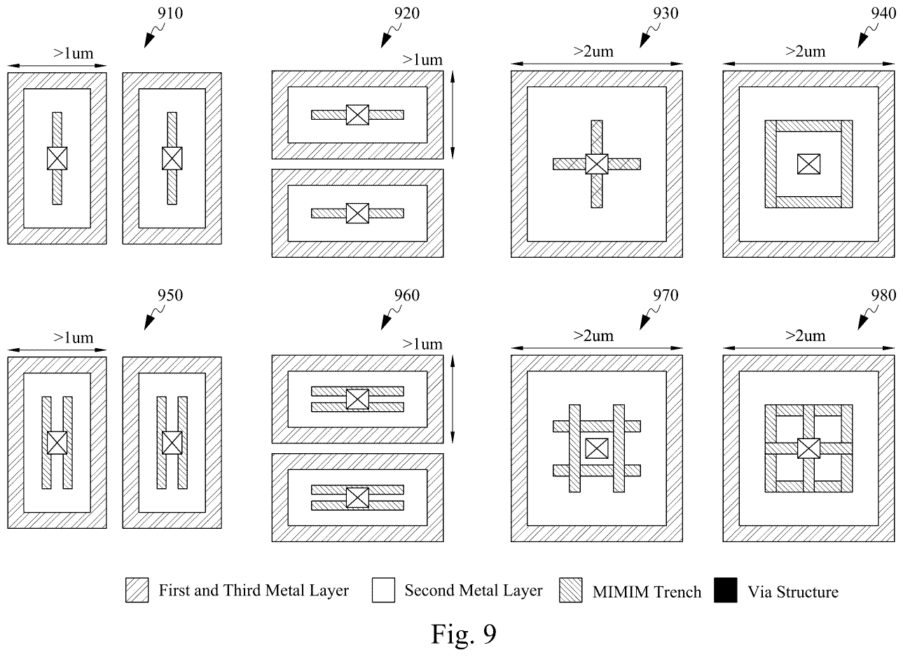

FIG. 9 illustrates top views of semiconductor devices 910, 920, 930, 940, 950, 960, 970, and 980, in accordance with some embodiments. Shown in the figures are non-limiting examples. In some embodiments, the semiconductor devices 910, 920, 930, 940, 950, 960, 970, and 980 can include more, fewer, or different components than shown in or described with respect to the figures. In some embodiments, the semiconductor devices 910, 920, 930, 940, 950, 960, 970, and 980 may be substantially similar to or incorporate features of the semiconductor devices 100, 400, 800 of FIG. 8A, etc. For example, the semiconductor devices 910, 920, 930, 940, 950, 960, 970, and 980 may be top views of the semiconductor devices 100, 400, etc. Each of the semiconductor devices 910, 920, 930, 940, 950, 960, 970, and 980 includes a capacitor, including a first metal layer, a second metal layer, and a dielectric layer, which form a MIM trench that is electrically connected (e.g., to an epitaxial structure) through a via structure.

As shown in FIG. 9, the geometry, dimension, etc. of the MIM trench, the first metal layer, the second metal layer, and the dielectric layer can vary. In some embodiments, as with the semiconductor device 910, the capacitors can be arrayed in parallel. As shown with the semiconductor device 950, each of the arrayed capacitors can have a plurality of MIM trench structures. As shown with the semiconductor devices 920 and 960, the capacitors can be arrayed with various orientations. Although shown as being arrayed in parallel (e.g., the semiconductor devices 910, 920, 950, 960), the capacitors can be arrayed or arranged in flexible manners. As shown with the semiconductor devices 930, 940, 970, and 980, the geometry, dimension, etc. of the MIM trench structure can vary. For example, the MIM trench can have a shape of a cross, a rectangle, a combination thereof, etc.

It should be understood that the semiconductor devices of FIG. 9 are non-limiting examples and simplified for illustrative purposes, and thus, can include any of various other components or structures, while remaining within the scope of the present disclosure. In some embodiments, the semiconductor device 800 can include more, fewer, or different components than shown in or described with respect to FIG. 9.

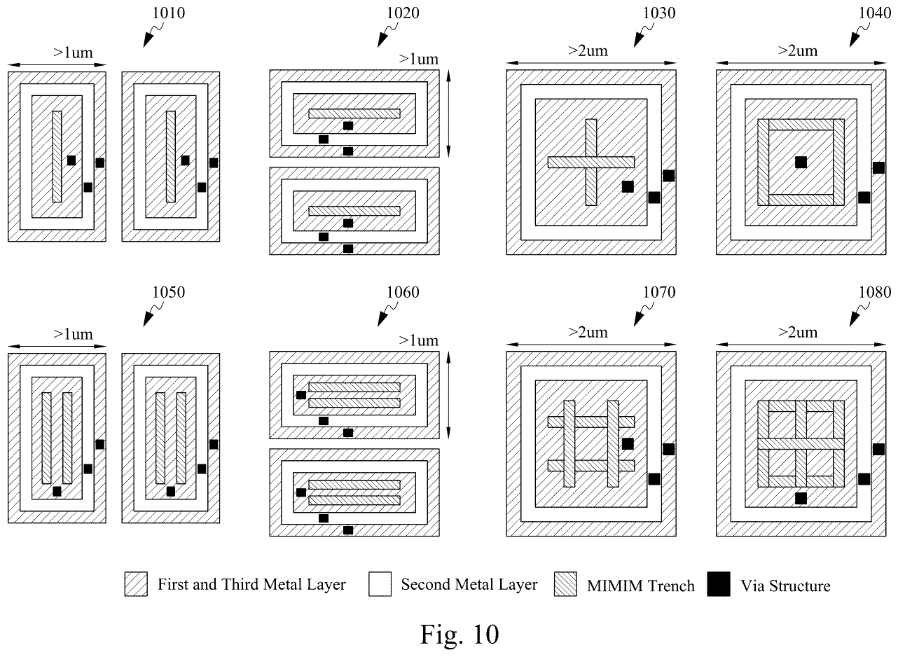

FIG. 10 illustrates top views of semiconductor devices, in accordance with some embodiments. Shown in the figures are non-limiting examples. In some embodiments, the semiconductor devices 1010, 1020, 1030, 1040, 1050, 1060, 1070, and 1080 can include more, fewer, or different components than shown in or described with respect to the figures. In some embodiments, the semiconductor devices 1010, 1020, 1030, 1040, 1050, 1060, 1070, and 1080 may be substantially similar to or incorporate features of the semiconductor devices 100, 400, 800 of FIG. 8B, etc. For example, the semiconductor devices 1010, 1020, 1030, 1040, 1050, 1060, 1070, and 1080 may be top views of the semiconductor devices 100, 400, etc. Each of the semiconductor devices 1010, 1020, 1030, 1040, 1050, 1060, 1070, and 1080 includes a capacitor, including a first metal layer, a second metal layer, and a dielectric layer, which form a MIMIM trench that is electrically connected (e.g., to a plurality of epitaxial structures) through a plurality of via structures.

As shown in FIG. 10, the geometry, dimension, etc. of the MIMIM trench, the first metal layer, the second metal layer, and the dielectric layer can vary. In some embodiments, as with the semiconductor device 1010, the capacitors can be arrayed in parallel. As shown with the semiconductor device 1050, each of the arrayed capacitors can have a plurality of MIMIM trench structures. As shown with the semiconductor devices 1020 and 1060, the capacitors can be arrayed with various orientations. Although shown as being arrayed in parallel (e.g., the semiconductor devices 1010, 1020, 1050, 1060), the capacitors can be arrayed or arranged in flexible manners. As shown with the semiconductor devices 1030, 1040, 1070, and 1080, the geometry, dimension, etc. of the MIMIM trench structure can vary. For example, the MIMIM trench can have a shape of a cross, a rectangle, a combination thereof, etc.

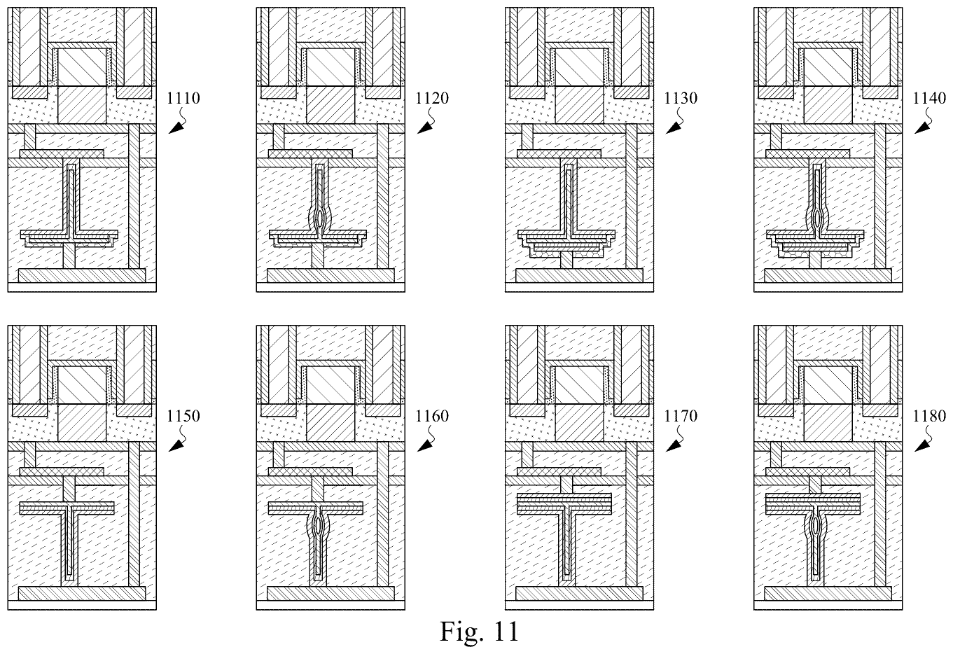

As discussed above, the semiconductor devices of the present disclosure can include various features, for example, whether the vertical portion of the metal layers and dielectric layer extends toward or away from the substrate; whether the semiconductor device includes a third metal layer (e.g., the third metal layer 863); whether the semiconductor devices includes a void (e.g., the void 760V), etc. Based on these features, the semiconductor devices can be designed in various ways. For example, non-limiting examples of semiconductor devices are summarized below in Table 1, referring to FIG. 11. FIG. 11 illustrates cross-sectional views of semiconductor devices 1110, 1120, 1130, 1140, 1150, 1160, 1170, 1180, in accordance with some embodiments.

TABLE 1

| Toward | v | v | v | v | | | | |
|---|---|---|---|---|---|---|---|---|
| Away from | | | | | v | v | v | v |
| MIM | v | v | | | v | v | | |
| MIMIM | | | v | v | | | v | v |
| Void w/ | | v | | v | | v | | v |
| Bowing | | | | | | | | |
| FIG. 10 | 1110 | 1120 | 1130 | 1140 | 1150 | 1160 | 1170 | 1180 |

For example, the semiconductor device 1110 includes a vertical portion extending toward a first substrate (or a top portion) with a MIM trench, and the semiconductor device 1120 additionally includes a void with a bowing profile. The semiconductor device 1130 includes a vertical portion extending toward a first substrate (or a top portion) with a MIMIM trench (as the semiconductor device 1130 includes a third metal layer), and the semiconductor device 1140 additionally includes a void with a bowing profile. Likewise, the semiconductor device 1150 includes a vertical portion extending away from the first substrate (or the top portion) with a MIM trench, and the semiconductor device 1160 additionally includes a void with a bowing profile. The semiconductor device 1170 includes a vertical portion extending toward the first substrate (or the top portion) with a MIMIM trench (as the semiconductor device 1170 includes a third metal layer), and the semiconductor device 1180 additionally includes a void with a bowing profile.

It should be understood that the semiconductor devices of FIG. 11 are non-limiting examples and simplified for illustrative purposes, and thus, can include any of various other components or structures, while remaining within the scope of the present disclosure. In some embodiments, the semiconductor devices of FIG. 11 can include more, fewer, or different components than shown in or described with respect to FIG. 11.

In one aspect of the present disclosure, a semiconductor device is disclosed. The semiconductor device includes a first substrate including a first side and a second side opposite to each other. The semiconductor device includes a plurality of epitaxial structures and at least a gate structure formed on the first side of the first substrate, a second substrate including a first side and a second side opposite to each other, a first metal layer formed on the first side of the second substrate, a second metal layer formed on the first side of the second substrate, a dielectric layer interposed between the first metal layer and the second metal layer, and a bonding layer interposed between the second side of the first substrate and the second side of the second substrate. The first metal layer, the second metal layer, and the dielectric layer operatively form a capacitor on the first side of the second substrate that is coupled to at least one of the plurality of epitaxial structures on the first side of the first substrate. Each of the first metal layer, the dielectric layer, and the second metal layer includes at least a vertical portion extending toward or away from the first substrate.

In another aspect of the present disclosure, a semiconductor device is disclosed. The semiconductor device includes a substrate including a first side and a second side opposite to each other, a plurality of transistors formed on the first side of the substrate, a first metal layer formed on the second side of the substrate, a second metal layer formed on the second side of the substrate, and a dielectric layer interposed between the first metal layer and the second metal layer. Each of the first metal layer, the dielectric layer, and the second metal layer includes a vertical portion extending toward or away from the first side of the substrate and a lateral portion connected to the vertical portion.

In yet another aspect of the present disclosure, a method for forming semiconductor devices is disclosed. The method includes forming, on a front side of a first substrate, a plurality of transistors, wherein each of the plurality of transistors includes at least one epitaxial structure, forming, on a front side of a second substrate, a first metal layer, a second metal layer, and a dielectric layer interposed between the first and second metal layers, wherein each of the first metal layer, the dielectric layer, and the second metal layer includes a vertical portion extending toward or away from the second substrate, and bonding the first substrate to the second substrate, with a backside of the first substrate facing a backside of the second substrate.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., +10%, +20%, or +30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device, comprising:
a first substrate including a first side and a second side opposite to each other;
a plurality of epitaxial structures and at least one gate structure formed on the first side of the first substrate;
a second substrate including a first side and a second side opposite to each other;
a first metal layer formed on the first side of the second substrate;
a second metal layer formed on the first side of the second substrate;
a dielectric layer interposed between the first metal layer and the second metal layer; and
a bonding layer interposed between the second side of the first substrate and the second side of the second substrate;
wherein the first metal layer, the second metal layer, and the dielectric layer operatively form a capacitor on the first side of the second substrate that is coupled to at least one of the plurality of epitaxial structures on the first side of the first substrate, and wherein each of the first metal layer, the dielectric layer, and the second metal layer includes at least a vertical portion extending toward or away from the first substrate.

2. The semiconductor device of claim 1, wherein the first metal layer is disposed in a first one of a plurality of metallization layers formed on the first side of the second substrate, and the second metal layer is disposed in a second one of the plurality of metallization layers.

3. The semiconductor device of claim 2, wherein a first metallization layer and a second metallization layer are vertically disposed next to each other, with no other metallization layer interposed therebetween.

4. The semiconductor device of claim 2, wherein a first metallization layer and a second metallization layer are vertically disposed next to each other, with at least another of the plurality of metallization layers interposed therebetween.

5. The semiconductor device of claim 1, wherein the dielectric layer includes a high-k dielectric material.

6. The semiconductor device of claim 1, wherein the dielectric layer includes a ferroelectric material.

7. The semiconductor device of claim 1, wherein the first metal layer is electrically coupled to a first one of the plurality of epitaxial structures, and the second metal layer is electrically coupled to a second one of the plurality of epitaxial structures.

8. The semiconductor device of claim 1, wherein the plurality of epitaxial structures are laterally disposed on sides of the at least one gate structure.

9. The semiconductor device of claim 1, wherein the first metal layer and the second metal layer each include copper or aluminum.

10. The semiconductor device of claim 1, wherein the first metal layer and the second metal layer include different materials.

11. The semiconductor device of claim 1, wherein each of the first metal layer, the dielectric layer, and the second metal layer includes one or more lateral portions connected to a corresponding vertical portion.

12. A semiconductor device, comprising:
a substrate including a first side and a second side opposite to each other;
a plurality of transistors formed on the first side of the substrate;
a first metal layer formed on the second side of the substrate;
a second metal layer formed on the second side of the substrate; and
a dielectric layer interposed between the first metal layer and the second metal layer;
wherein each of the first metal layer, the dielectric layer, and the second metal layer includes a vertical portion extending toward or away from the first side of the substrate and a lateral portion connected to the vertical portion.

13. The semiconductor device of claim 12, wherein the first metal layer, the dielectric layer, and the second metal layer operatively form a capacitor.

14. The semiconductor device of claim 12, wherein the dielectric layer includes one of a ferroelectric material or a high-k dielectric material.

15. The semiconductor device of claim 12, wherein the first metal layer and the second metal layer each include copper or aluminum.

16. The semiconductor device of claim 12, further comprising a third metal layer formed between the first metal layer and the second metal layer, within the dielectric layer.

17. The semiconductor device of claim 16, wherein the first metal layer, the second metal layer, the third metal layer within the dielectric layer, and the dielectric layer form a plurality of capacitors that are connected in parallel to each other.

18. A method for forming semiconductor devices, comprising:
forming, on a front side of a first substrate, a plurality of transistors, wherein each of the plurality of transistors includes at least one epitaxial structure;
forming, on a front side of a second substrate, a first metal layer, a second metal layer, and a dielectric layer interposed between the first metal layer and the second metal layer, wherein each of the first metal layer, the dielectric layer, and the second metal layer includes a vertical portion extending toward or away from the second substrate; and
bonding the first substrate to the second substrate, with a backside of the first substrate facing a backside of the second substrate.

19. The method of claim 18, further comprising:
forming an interlayer dielectric over a frontside of the second substrate;
etching the interlayer dielectric to form a trench;
depositing a metal material to at least line the trench thereby forming the first metal layer;
depositing a dielectric material to at least line the trench thereby forming the dielectric layer; and
depositing the metal material to fill the trench thereby forming the second metal layer;
wherein the metal material is copper.

20. The method of claim 18, further comprising:
depositing a metal material over a frontside of the second substrate;
etching the metal material thereby forming the first metal layer;
depositing a dielectric material to line the first metal layer thereby forming the dielectric layer;
depositing the metal material to line the dielectric layer thereby forming the second metal layer;
wherein the metal material is aluminum
